(19) United States
(12) Patent Application Publication
(10) Pub. No.: US 2007/0122938 A1
(43) Pub. Date: May 31, 2007

(54) Organic electroluminescent display device

(76) Inventor: Haruo Tanaka, Shiga (JP)

Correspondence Address: HOGAN & HARTSON L.L.P., 1999 AVENUE OF THE STARS, SUITE 1400, LOS ANGELES, CA, 90067, US

(21) Appl. No.: 10/581,235

(22) PCT Filed: Sep. 9, 2004
(86) PCT No.: PCT/JP04/13133

§ 371 Date: Jun. 2, 2006

(30) Foreign Application Priority Data
Dec. 4, 2003 (JP) 2003-405507

(51) Int. Cl. H01L 29/08; H01L 51/40; H01L 21/00

(52) U.S. Cl. 438/99; 438/120; 257/40

(57) ABSTRACT

It is an object of the present invention to provide an organic EL display that has a display device such that decrease in the quality of light emitted in an organic light-emitting layer can be suppressed, operates with a low driving voltage and can emit light efficiently.

In order to solve the above problem, in an organic EL display 10 of the present invention having a plurality of display device 20 provided onto a substrate 30, the display devices includes: an anode electrode 31 arranged on the substrate, a cathode electrode 32 arranged adjacently to the anode electrode; an organic light-emitting layer 38 which emits light by means of an electric field to be supplied from the anode electrode and the cathode electrode and is formed on the substrate so as to cover both the anode electrode and the cathode electrode; and a separator 42 in a substrate laminating direction which is arranged between the anode electrode and the cathode electrode and separates to insulate at least the anode electrode and the cathode electrode. A carbon nanotube is mixed in the organic light-emitting layer.

### TECHNICAL FIELD

The resent invention relates to an organic electroluminescence display that uses an organic electroluminescence display device.

### BACKGROUND ART

In recent years, organic electroluminescence displays that utilize organic electroluminescence emission (hereinafter, “electroluminescence” is referred to as “EL”) are being developed. Display devices which are used in conventional organic EL displays are constituted so that a light-emitting layer which organically emits light is sandwiched by an anode electrode and a cathode electrode (for example, see patent document 1).

FIG. 11 illustrates a schematic constitutional diagram of a display device to be used in conventional organic EL displays. The conventional display device 100 has a substrate 101 made of a transparent insulating material such as glass, a transparent electrode as an anode electrode 102 provided onto the substrate 101, a light-emitting layer 104 for organic light emission, a hole transport layer 103 as a buffer layer which improves joint property of the anode electrode 102 and the light-emitting layer 104, a cathode electrode 106 made of a material such as aluminum with small work function, an electron transport layer 105 as a buffer layer which improves joint property of the cathode electrode 106 and the light-emitting layer 104, and the like.

Light emitted in the light-emitting layer 104 is emitted outside from a side of the substrate 101 and the cathode electrode 106 whose thickness is very thin, or is reflected by the cathode electrode 106 so as to be emitted from the side of the substrate 101. At this time, in the display device 100, since the light emitted in the light-emitting layer 104 transmits through the cathode electrode 106 or the transparent electrode and the substrate 101, the quantity of the transmitted light becomes smaller than the quantity of the light emitted in the light-emitting layer 104 due to reflection or absorption by the cathode electrode 106 and the substrate 101. Further, when the ITO is used as the transparent electrode which is the anode electrode 102, emitting light becomes occasionally reddish because ITO has wavelength selectivity such that transmission is easy to be performed on a long wavelength side of visible light.

Therefore, a display device which solves the above problem is developed. FIG. 12 illustrates a schematic constitutional diagram of the display device which solves the above problem. In the display device 200 shown in FIG. 12, an anode electrode 202 and a cathode electrode 206 are arranged in parallel on a substrate 201, and a light-emitting layer 204 is formed thereon so as to cover the anode electrode 202 and the cathode electrode 206. Further, a separator 203 is provided in a substrate laminating direction in order to separate to insulate the anode electrode 202 from the cathode electrode 206. In the display device 200, since light emitted in the light-emitting layer 204 is not transmitted through a member such as the substrate 201 and can be emitted directly from a side opposite to the substrate 201, a change in light spectrum such that the light quantity is reduced or emitted light is reddish is not caused.

Since, however, the anode electrode 202 and the cathode electrode 206 are arranged in parallel, a moving distance of electrons and holes which move in the light-emitting layer 204 becomes long. When the moving distance of the electrons and the holes becomes long, a driving voltage of the display device 200 should be increased, and thus it is difficult to efficiently emit light in the light-emitting layer 204 with respect to the driving voltage of the display device 200. Patent document 1: Japanese Patent Application Laid-Open No. 2001-43980

### DISCLOSURE OF THE INVENTION

It is, therefore, an object of the present invention to provide an organic EL display which has a display device having a constitution such that decrease in the quantity of light emitted in an organic light-emitting element can be suppressed, operates with low driving voltage, and can emit light efficiently.

In order to solve the above problem, in an organic EL display of the present invention, an anode electrode and a cathode electrode are arranged on a substrate so as to be adjacent to each other, and an organic light-emitting element is formed so as to cover the anode electrode and the cathode electrode. Further, in order to reduce a driving voltage of the organic EL display, a carbon nanotube is mixed partially in the organic light-emitting element.

The carbon nanotube is a substance which is made of carbon where a graphite sheet is formed into a tube shape with diameter of several nm, and it is known that its electrical conductivity is larger than that of metal such as iron and copper. When the carbon nanotube is mixed partially in the organic light-emitting element, mobility of electrons and holes moving in the organic light-emitting element is improved, and resistance of the organic light-emitting element per unit volume can be expected to be reduced.

For this reason, a voltage is concentrated on the light-emitting unit as a light emitting area of the organic light-emitting element, and an improvement of luminous efficacy can be expected while the driving voltage is being reduced.

Concretely, in the organic EL display of the present invention having a plurality of display devices provided on the substrate, the display devices includes: a first electrode element arranged on the substrate; a second electrode element arranged adjacently to the first electrode element; an organic light-emitting element that emits light by an electric field supplied by the first electrode element and the second electrode element and is formed on the substrate so as to cover both the first electrode element and the second electrode element; and a separator in a substrate laminating direction that is arranged between the first electrode element and the second electrode element and separates to insulate at least the first electrode element from the second electrode element. A carbon nanotube is mixed in the organic light-emitting element.

According to the above invention, since the organic EL display has a constitution where the light emitted in the organic light-emitting element can be emitted directly from the organic light-emitting element, decrease in the quantity of the emitted light can be suppressed, and a change in spectrum of the emitted light such that the emitted light becomes reddish is not caused. Further, the driving voltage of the organic EL display can be reduced by the carbon nanotube mixed in the organic light-emitting element.

In another organic EL display of the present invention, the carbon nanotube is mixed between a surface crossing the organic light-emitting element in the organic light-emitting element on the side closer to the first electrode than the separator and the first electrode element.

When the carbon nanotube is mixed in the above position, mobility of the holes in the carbon nanotube mixed portion is heightened, and electric resistance of the organic light-emitting element between the first electrode element and the second electrode element can be small.

Further, in another organic EL display of the present invention, the carbon nanotube is mixed between a surface crossing the organic light-emitting element in the organic light-emitting element on the side closer to the second electrode element than the separator and the second electrode element.

When the carbon nanotube is mixed in the above position, the mobility of the electrons in the carbon nanotube mixed portion is heightened. As a result, the carbon nanotube mixed portion becomes an electron source, so that an applied voltage can be concentrated on the light-emitting unit in the organic light-emitting element, and the driving voltage of the organic EL display can be small.

Further, in another organic EL display of the present invention, the carbon nanotube is mixed between a surface crossing the organic light-emitting element in the organic light-emitting element on the side closer to the first electrode than the separator and the first electrode element, and between a surface crossing the organic light-emitting element in the organic light-emitting element on the side closer to the second electrode element than the separator and the second electrode element.

When the carbon nanotube is mixed in the above position, the mobility of the holes in the carbon nanotube mixed portion is heightened, so that the electric resistance of the organic light-emitting element between the first electrode element and the second electrode element can be small. When the mobility of the electrons in the carbon nanotube mixed portion is heightened, the carbon nanotube mixed portion becomes an electron source, so that the applied voltage can be concentrated on the light-emitting unit in the organic light-emitting element. As a result, the driving voltage of the organic EL display can be small.

Further, in another organic EL display of the present invention, the carbon nanotube is mixed between a surface crossing the organic light-emitting element in the organic light-emitting element on the side closer to the first electrode element than the separator and the second electrode element.

When the carbon nanotube is mixed in the above position, the mobility of the electrons in the carbon nanotube mixed portion is heightened, so that the carbon nanotube mixed portion becomes an electron source. The applied voltage can be concentrated on the light-emitting unit in the organic light-emitting element, thereby reducing the driving voltage of the organic EL display.

Further, in another organic EL display of the present invention, the carbon nanotube is mixed between a surface crossing the organic light-emitting element in the organic light-emitting element on the side closer to the second electrode element than the separator and the first electrode element.

When the carbon nanotube is mixed in the above position, the mobility of the holes in the carbon nanotube mixed portion is heightened, so that the electric resistance of the organic light-emitting element can be small between the first electrode element and the second electrode element.

In the organic EL display of the present invention, it is desirable that at least one of the first electrode element and the second electrode element is formed transparently.

When the transparent material is used for the substrate, the light emitted in the organic light-emitting element can be transmitted through the electrode element formed transparently to be emitted from the side of the substrate. As a result, both the surfaces of the organic EL display can be display surfaces.

Further, in the organic EL display, it is desirable that both the first electrode element and the second electrode element are made of a material having resistivity of smaller than 10⁻⁴ Ω·cm.

When both the first electrode element and the second electrode element are made of the above material, the joint property of the organic light-emitting element and the first electrode element and the second electrode element is improved, so that the light can be emitted in the organic light-emitting element efficiently with respect to the driving voltage of the organic EL display.

Further, in the organic EL display, it is desirable that a plurality of the band-shaped first electrode elements are arranged in a line form, and a plurality of the band-shaped second electrode elements are arranged in a line form via an insulating layer so as to cross the first electrode elements.

The organic EL display where the first electrode element and the second electrode element are arranged in a matrix pattern so as to enable image display is proposed.

Further, in the organic EL display, it is desirable that a plurality of band-shaped grooves are provided in a line form on the first electrode elements so as to cross the first electrode elements, the second electrode elements are arranged in the grooves, respectively, via the insulating layer, and a height of a boundary between the first electrode elements and the organic light-emitting element from the substrate is approximately equal to a height of a boundary between the second electrode elements and the organic light-emitting element from the substrate.

When the surfaces of the first electrode element and the second electrode element are aligned, the moving distance of the electrons moving in the organic light-emitting element becomes shorter than the moving distance of the electrons moving in the organic light-emitting element formed into a thickness which is the same as that of the second electrode element. As a result, the light can be emitted efficiently in the organic light-emitting element with respect to the driving voltage of the organic EL display.

Further, in the organic EL display, it is desirable that the first electrode element has an anode side function element which is adjacent to the organic light-emitting element and has at least one of a hole transport function and a hole injecting function, and/or the second electrode element has a cathode side function element which is adjacent to the organic light-emitting element and has at least one of an electron transport function and an electron injecting function, and the first electrode element serves as an anode and the second electrode element serves as a cathode.

When a buffer layer intervenes between the first electrode element and the organic light-emitting element and between the second electrode element and the organic light-emitting element, the joint property of the first electrode element and the organic light-emitting element, and the joint property of the second electrode element and the organic light-emitting element are improved. As a result, the light can be emitted efficiently in the organic light-emitting element with respect to the organic EL display.

In the organic EL display of the present invention which has the display devices having the constitution such that decrease in the quantity of the light emitted in the organic light-emitting element can be suppressed, the driving voltage of the organic EL display can be reduced. Further, light can be emitted efficiently in the organic light-emitting element with respect to the driving voltage of the organic EL display.

### BRIREF DESCRIPTION OF THE DRAWINGS

FIG. 1 is a schematic constitutional diagram illustrating one example of a display device which is a constitutional unit of an organic EL display according to one embodiment of the present invention;

FIG. 2 is an enlarged schematic diagram illustrating one example of a form of a carbon nanotube mixed portion of an organic light-emitting layer;

FIG. 3 is an enlarged schematic diagram illustrating one example of the form of the carbon nanotube mixed portion of the organic light-emitting layer;

FIG. 4 is a schematic constitutional diagram illustrating one example of the organic EL display according to the embodiment of the present invention;

FIG. 5 is a schematic constitutional diagram illustrating one example of a constitution of the display device;

FIG. 6 is a schematic constitutional diagram illustrating one example of the constitution of the display device;

FIG. 7 is a schematic constitutional diagram illustrating one example of the constitution of the display device;

FIG. 8 is a schematic constitutional diagram illustrating one example of the constitution of the display device;

FIG. 9 is a schematic constitutional diagram illustrating one example of the constitution of the display device;

FIG. 10 is a schematic constitutional diagram illustrating one example of the constitution of the display device;

FIG. 11 is a schematic constitutional diagram of a display device to be used in a conventional EL display; and

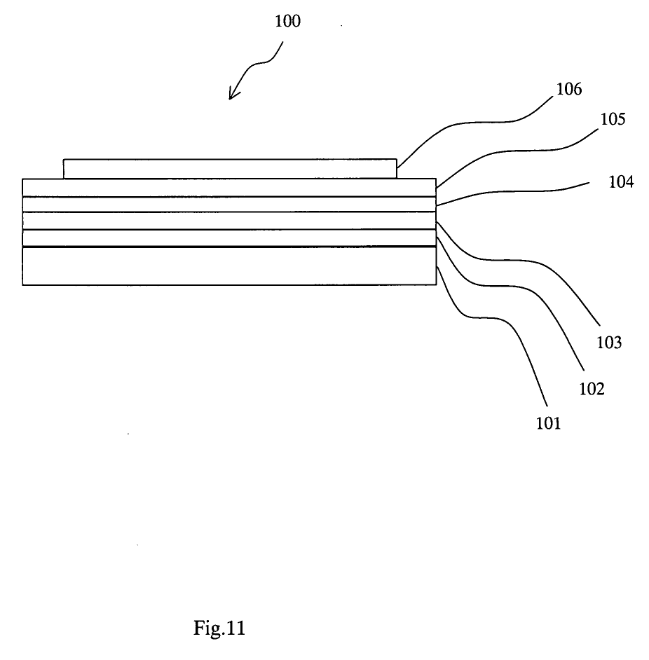

FIG. 12 is a schematic constitutional diagram of a display device to be used in a conventional EL display.

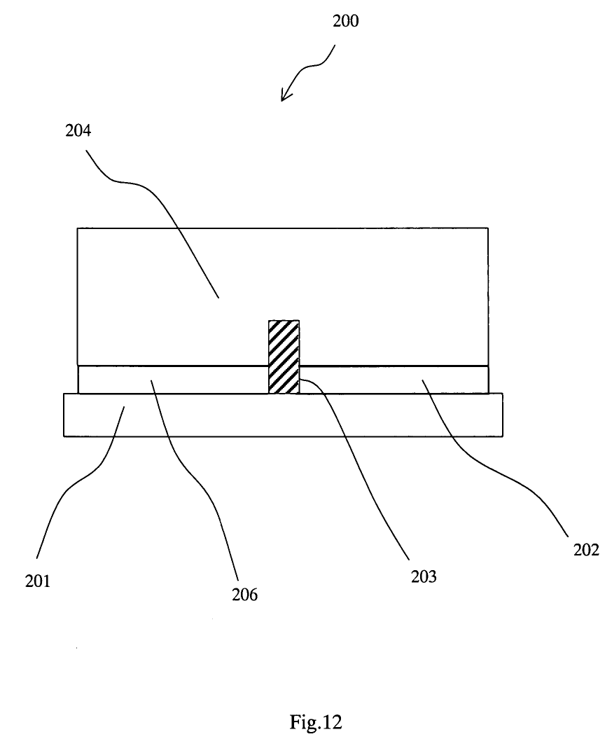

### DESCRIPTION OF REFERENCE NUMERALS

10: organic EL display
20: display device
30: substrate
31: anode electrode
32: cathode electrode
33: insulating layer
34: hole transport layer
35: hole injecting layer
36: electron injecting layer
37: electrode transport layer
38: organic light-emitting layer
41: insulating member
42: separator
43: groove 51, 52, 53, 54, 55: organic light-emitting layer including carbon nanotube
60: light-emitting unit
100: display device
101: substrate
102: anode electrode
103: hole transport layer
104: light-emitting layer
105: electron transport layer
106: cathode electrode
200: display device
201: substrate
202: anode electrode
203: separator
204: light-emitting layer
206: cathode electrode

### BEST MODE FOR CARRYING OUT THE INVENTION

Embodiments of the present invention are explained in detail below with reference to the drawings, but the present invention is not limited to the description.

### FIRST EMBODIMENT

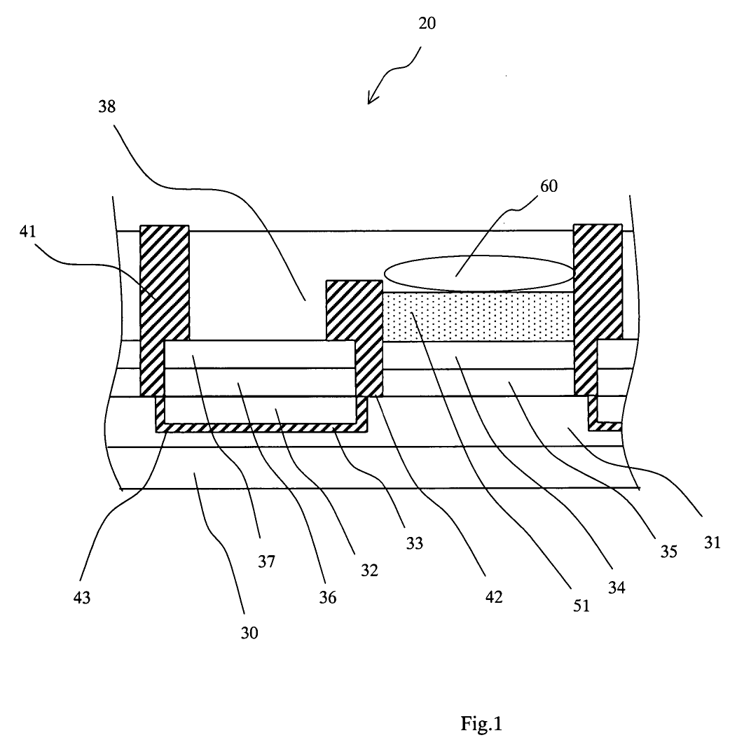

FIG. 1 illustrates a schematic constitutional diagram of a display device which is a constitutional unit of an organic EL display of the present invention. The display device 20 shown in FIG. 1 has an anode electrode 31 as a first electrode element arranged on a substrate 30, a cathode electrode 32 as a second electrode element arranged adjacently to the anode electrode 31, an organic light-emitting layer 38 as an organic light-emitting element which emits light due to an electric field supplied by the anode electrode 31 and the cathode electrode 32 and is formed on the substrate 30 so as to cover both the anode electrode 31 and the cathode electrode 32 and in which a carbon nanotube is mixed partially, and a separator 42 which is arranged between the anode electrode 31 and the cathode electrode 32 in a substrate laminating direction and at least separates to insulate the first electrode element side from the second electrode element side. Furthermore, the first electrode element may have a hole injecting layer 35 and a hole transport layer 34 as anode side functional elements that improve joint property with respect to the organic light-emitting layer 38, and the second electrode element may have an electron injecting layer 36 and an electron transport layer 37 as cathode side functional elements which improve joint property with respect to the organic light-emitting layer 38. Further, an insulating member 41 which separates to insulate the display devices 20 may be provided.

In the display device 20 shown in FIG. 1, in order to solve conventional problems such as decrease in emitted light from the display device emitted of the light emitted in the organic light-emitting layer or a change in spectrum or the like, the substrate 30, the anode electrode 31, the cathode electrode 32 and the organic light-emitting layer 38 are laminated in this order. Due to such a constitution of the display device 20, in the case where the laminating direction is a first direction and the opposite direction is a second direction, light generate in the organic light-emitting layer 38 is not transmitted through the substrate 30 and the electrodes, and the light can be led directly to the first direction from the organic light-emitting layer 38. Since, therefore, reflection loss due to a difference in refractive index and transmission loss due to absorption can be reduced more than the case where the light is transmitted through the electrodes and the substrate so as to be emitted, improvement in emission efficiency of the light to be finally emitted to the outside can be expected. Further, since the light can be emitted without being transmitted through the electrodes or the like, the spectrum of the emitted light is not changed.

Since the anode electrode 31 and the cathode electrode 32 are arranged adjacently, however, a moving distance of electrons and holes moving in the organic light-emitting layer 38 becomes long. When the moving distance of the electrons and the holes becomes long, a driving voltage of the display device 20 should be increased, and thus it is difficult to efficiently emit light in the organic light-emitting layer 38 with respect to the driving voltage of the display device 20. In this embodiment, therefore, a carbon nanotube is mixed partially in the organic light-emitting layer 38. This will be described later.

The substrate 30 has a first surface on which the display device 20 is formed, and a second surface which can be one of emission surfaces when the anode electrode 31 and the substrate 30 are made of a transparent material. Hereinafter, a direction of the light to be transmitted through the second surface of the substrate 30 and emitted is a second direction, and a direction of the light to be emitted to the opposite direction is a first direction. It is desirable that an insulating material is used as the substrate 30. Its examples are transparent glass, plastic and plastic film. When the substrate 30 is transparent, the light emitted in the organic light-emitting layer 38 can be led to the second direction. Further, since the light emitted in the organic light-emitting layer 38 can be led to the first direction, an opaque material may be used as the substrate 30. For this reason, a silicon substrate which is opaque but has high thermal diffusivity can be used as the substrate 30. When the silicon substrate is adopted as the substrate 30, thermal deterioration of the organic light-emitting layer 38 can be suppressed, and the life of the display device 20 can be long.

The anode electrode 31 is formed so as to cover the substrate 30. At this time, when a transparent electrode such as ITO is used as the anode electrode 31 and the substrate 30 is made of a transparent material, the light emitted in the organic light-emitting layer 38 can be emitted to the second direction. Further, since the light emitted in the organic light-emitting layer 38 can be led to the first direction, materials such as copper (resistivity: 1.67×10⁻⁶ Ω·cm) and aluminum (resistivity: 2.655×10⁻⁶ Ω·cm) which are opaque but has resistivity of smaller than 10⁻⁴ Ω·cm can be used as the anode electrode 31. For this reason, the light can be emitted in the organic light-emitting layer 38 efficiently by a low driving voltage.

The cathode electrode 32 is arranged in a groove 43 provided on the anode electrode 31 via the insulating layer 33. When the cathode electrode 32 is arranged in the groove 43, electrode surfaces of the anode electrode 31 and the cathode electrode 32 can be approximately aligned with each other. When a difference in the height of the electrode surfaces is eliminated, the thickness of the organic light-emitting layer 38 to be formed on the anode electrode 31 and the cathode electrode 32 can be reduced, and decrease in mobility of the electrons in such a manner that the mobility is decreased in inverse proportion to third root of the volume of the organic light-emitting layer 38 can be suppressed. In the case where the first electrode element serves as the anode, the second electrode element serves as the cathode. At this time, it is desirable that a material which has small work function or small electron affinity is used as the cathode electrode 32 in order to make reflectance high and facilitate the injection of electrons into the organic light-emitting layer 38. For example, materials such as magnesium silver alloy and aluminum-lithium alloy can be used. Further, materials with resistivity smaller than 10⁻⁴ Ω·cm such as copper (resistivity: 1.67×10⁻⁶ Ω·cm) and aluminum (resistivity: 2.655×10⁻⁶ Ω·cm) can be used. When the material with resistivity smaller than 10⁻⁴ Ω·cm is used as the cathode electrode 32, the light can be emitted in the organic light-emitting layer 38 efficiently by a low driving voltage.

The separator 42 is provided in the substrate laminating direction so as to separate to insulate the first electrode element from the second electrode element. The provision of the separator 42 ensures the moving of the holes induced from the anode electrode 31 and the electrons induced from the cathode electrode 32, so that the electrons and the holes can be induced appropriately to the organic light-emitting layer 38.

The anode side functional element has the hole injecting layer 35 which improves injecting efficiency of the holes from the anode electrode 31 as the first electrode element, and the hole transport layer 34 having the function of an electron barrier. Examples of materials of the hole injecting layer 35 are arylamine and phthalocyanine (copper phthalocyanine) . Further, an example of the material of the hole transport layer 34 is arylamine.

The cathode side functional element has the electron injecting layer 36 which improves injecting efficiency of electrons from the cathode electrode 32, and the electron transport layer 37 having the function of a hole barrier. Examples of the material as the electron injecting layer 36 are alkali metal, such as lithium, lithium fluoride, lithium oxide and lithium complex. Further, examples of the material of the electron transport layer 37 are aluminum complex, oxadiazole, triazole and phenanthroline.

The organic light-emitting layer 38 has a light-emitting unit 60 which emits light due to an electric field supplied by the anode electrode 31 and the cathode electrode 32. The light-emitting unit 60 is excited by recoupling of the electrons and the holes which move in the organic light-emitting layer 38 and emits light with high efficiency. A compound having light emitting property such that fluorescence or phosphorescence is strong is used as the organic light-emitting layer 38. The organic light-emitting layer 38 may include a host material whose light emitting ability is low but deposition property and luminescence are good, and a dopant pigment whose light emitting ability is high but cannot be deposited by itself. An example of the host material is aluminum complex. Examples of the dopant pigment are perylene (red light emitting material), and rubrene (orange light emitting material). At this time, a material of the dopant pigment which satisfies a condition that an excitation energy level of molecules of the host material is higher than an excitation energy level of the dopant pigment molecules is selected. Further, the carbon nanotube is mixed partially in the organic light-emitting layer 38.

The carbon nanotube is a substance which is made of carbon obtained in such a manner that a graphite sheet is formed into a tube shape with diameter of several nm, and includes a multi-layer one formed by overlapping a plurality of tubes and a single-layer one composed of only one tube. The carbon nanotube can be created by synthesizing methods such as carbon arc discharge, carbon laser evaporation, thermal decomposition of hydrocarbon gas, a plasma CVC (Chemical Vapour Deposition) method and an electron beam irradiation method. The single-layer carbon nanotube is classified into three types: chiral type; arm chair type; and zigzag type according to carbon coupling types. At this time, the arm chair and zigzag type carbon nanotubes have metallic electric conductivity, and the chiral type carbon nanotube has semiconductor type electric conductivity. In this embodiment, it is desirable that the armchair type and zigzag type carbon nanotubes having metallic electric conducting property are used. Since the electric conductivity of the carbon nanotube is extremely high, electric resistance of the organic light-emitting layer 38 in which the carbon nanotube is mixed can be smaller than electric resistance of the organic light-emitting layer in which the carbon nanotube is not mixed, and thus light can be efficiently emitted in the organic light-emitting layer 38 with respect to the driving voltage of the display device 20.

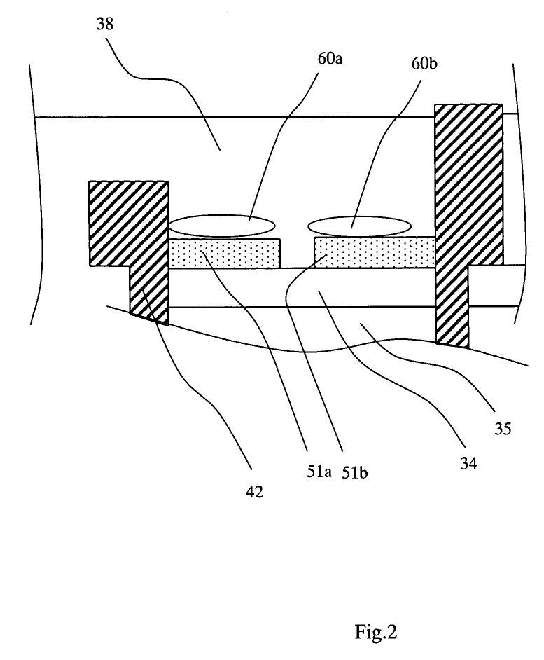

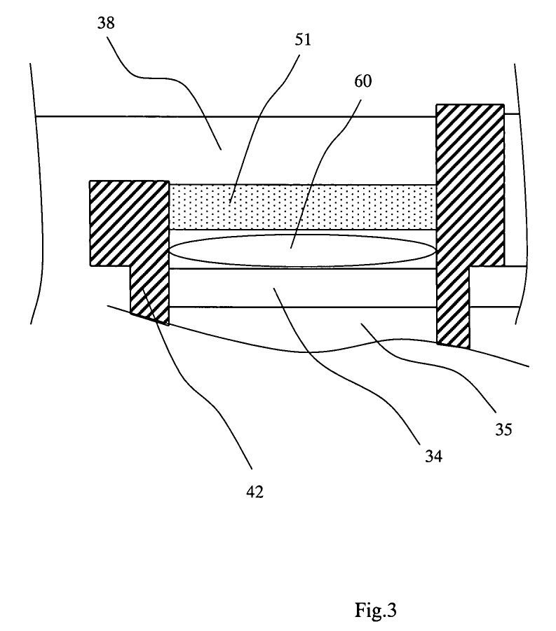

In this embodiment, the carbon nanotube is mixed between a surface crossing the organic light-emitting layer 38 in the organic light emitting layer 38 on the side closer to the anode electrode 31 than the separator 42 and the hole transport layer 34, so that an organic light-emitting layer 51 including the carbon nanotube is formed. For example as shown in FIG. 1, the carbon nanotube is mixed in the organic light-emitting layer 38 so as to cover the hole transport layer 34. FIGS. 2 and 3 are enlarged schematic diagrams illustrating another form of the carbon nanotube mixed portion of the inorganic light-emitting layer 38, but as shown in FIGS. 2 and 3, the carbon nanotube may be mixed in the organic light-emitting layer 38. This will be described later.

In the organic light-emitting layer 51 including the carbon nanotube shown in FIG. 1, since the carbon nanotube has small work function, it has a function for improving joint property with respect to the hole transport layer 34 and improving the mobility of the holes. When the carbon nanotube is mixed so as to cover the hole transport layer 34, the joint property can be improved in the entire area of the joint portion between the organic light-emitting layer 51 including the carbon nanotube and the hole transport layer 34. When the mobility of the hole is compared with the mobility of the electrons in the organic light-emitting layer 38, since the mobility of the electrons is relatively high, before the carbon nanotube is mixed in the organic light-emitting layer 38, it is considered that the holes and the electrons are recoupled in the vicinity of the boundary between the hole transport layer 34 and the organic light-emitting layer 38. When the carbon nanotube is mixed into the organic light-emitting layer 38 so that the mobility of the holes are improved, the holes can be easily retained in the vicinity of the boundary surface of the organic light-emitting layer 51 including the carbon nanotube opposite to the hole transport layer 34, and a position where the holes and the electrons are recoupled is assumed to be the vicinity of the boundary surface of the organic light-emitting layer 51 including the carbon nanotube opposite to the hole transport layer 34. When the light emitted in the organic light-emitting layer 38 is emitted to the first direction, the distance of transmission through the organic light-emitting layer 38 becomes short, so that the light emitting efficiency can be improved. When the carbon nanotube approximately covers the hole transport layer 34, even if a gap is present between the organic light-emitting layers 51a and 51b including the carbon nanotube as shown in FIG. 2, the holes can be easily retained in the vicinity of the boundary surface of the organic light-emitting layers 51a and 51b including the carbon nanotube opposite to the hole transport layer sufficiently and effectively.

Further, the carbon nanotube may be mixed in a position which does not contact with the hole transport layer 34 as shown in FIG. 3. At this time, it is desirable that the carbon nanotube is mixed so as to cross the organic light-emitting layer 38. In the organic light-emitting layer 51 including the carbon nanotube shown in FIG. 3, since the carbon nanotube has the function for improving the mobility of the electrons, its electric resistance becomes lower than that of the organic light-emitting layer 38 in which a carbon nanotube is not mixed. For this reason, the driving voltage can be reduced in comparison with the display device 20 having the organic light-emitting layer without the carbon nanotube.

When the carbon nanotube is mixed in the organic light-emitting layer 38, the driving voltage of the display device 20 can be reduced, and the light emitting efficiency of the organic light-emitting layer 38 with respect to the driving voltage of the display device 20 can be improved. Further, it is considered that an emission position of the light emitted in the organic light-emitting layer 38 can be finely adjusted.

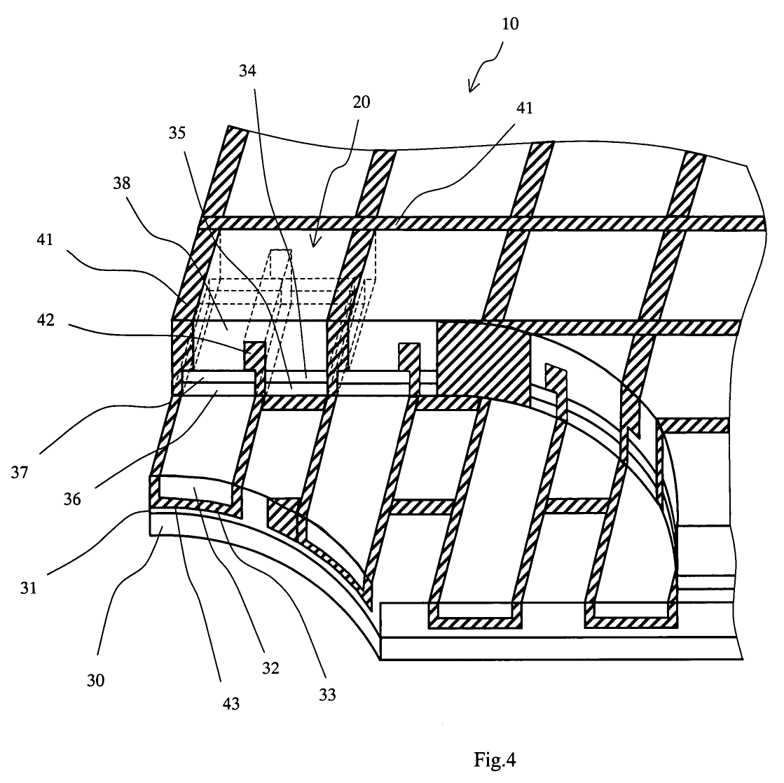

The organic light-emitting layer 38 can be formed by, for example, an ink-jet method. With the ink-jet method, a solution of an organic material is dropped from a head of the ink jet so that the organic light-emitting layer 38 is formed. At this time, the carbon nanotube may be mixed with the solution of the organic material. Firstly, the organic light-emitting layer 38 in which the carbon nanotube is not mixed is formed, and the solution of the organic material including the carbon nanotube is dropped thereon, so that the dropped portion becomes the organic light-emitting layer 51 including the carbon nanotube shown in FIG. 1. In the case where the organic light-emitting layer 38 is formed by the ink-jet method, since the insulating member 41 and the separator 42 shown in FIG. 4 block out the display devices 20 and inside the display devices, the formation of the organic light-emitting layer 38 is facilitated.

In this embodiment, the first electrode element is composed of the anode electrode 31, the hole transport layer 34 and the hole injecting layer 35, and the second electrode element is composed of the electron injecting layer 36, the electron transport layer 37 and the cathode electrode 32. Depending on the relationship with the organic light-emitting layer 38, however, the element may have the two-layer structure composed of the electron transport layer 37 and the organic light-emitting layer 38, or the hole transport layer 34 and the organic light-emitting layer 38, or may have the three-layer structure composed of the electron transport layer 37, the hole transport layer 34 and the organic light-emitting layer 38. In this embodiment, the first electrode element serves as the anode, and the second electrode element serves as the cathode, but “first” and “second” are only reference symbols for convenience.

The light emitting steps of the display device 20 in this embodiment are explained with reference to FIG. 1. The display device 20 is driven by, for example, a driver IC (not shown) which outputs a pulse voltage. When the a voltage of not less than a threshold value is applied to the anode electrode 31 and the cathode electrode 32 of the display device 20, the holes are injected from the anode electrode 31 into the hole injecting layer 35, and the electrons are injected from the cathode electrode 32 into the electrode injecting layer 36. The holes are transported into the organic light-emitting layer 38 via the hole transport layer 34, and the electrons are transferred into the organic light-emitting layer 38 via the electron transport layer 37. In the organic light-emitting layer 51 including the carbon nanotube, since the mobility of the holes and the electrons is improved, the holes and the electrons are recoupled in the vicinity of the light-emitting unit 60 so that an exciter is generated, and the exciter moves in the organic light-emitting layer 38. When the exciter discharges corresponding energy between bands of the dopant pigment so that the dopant pigment emits light.

The organic EL display using the above display device according to the present invention is explained below with reference to FIG. 4. FIG. 4 illustrates a schematic constitutional diagram of the organic EL display according to the embodiment. FIG. 4 partially includes a sectional view for easy understanding of the constitution of the organic EL display. The organic EL display 10 shown in FIG. 4 has the band-shaped anode electrodes 31 as the first electrode elements which are arranged in a line form, the band-shaped grooves 43 which are provided in a line form so as to cross the anode electrodes 31, the band-shaped cathode electrodes 32 as the second electrode elements which are arranged in a line form in the grooves 43 via the insulating layer 33, and the organic light-emitting layer 38 as the organic light-emitting element which is formed so as to cover the anode electrodes 31 and the cathode electrodes 32 and in which the carbon nanotube is mixed partially. The organic light-emitting layer 38 is separated to be insulated by the insulating member 41 in the substrate laminating direction, and respective insulated and separated elements emit light independently as the display devices 20.

In this embodiment, the anode electrode 31 covers the substrate 30. As a result, when a transparent electrode such as ITO is used as the anode electrode 31, a transparent insulating material such as glass is used as the substrate 30, so that the light emitted in the organic light-emitting layer 38 can be emitted from the substrate 30 side. Different two surfaces of the organic EL display 10 can be, therefore, used as the display surfaces.

When a plurality of the anode electrodes 31 and the cathode electrodes 32 are formed in a line form, the display devices 20 can be driven by passive driving in a line sequential direction. The passive driving is a driving method of applying a voltage to one anode electrode 31 and one cathode electrode 32 simultaneously so as to emit light at a portion in the organic light-emitting layer 38 where the anode electrode 31 and the cathode electrode 32 cross each other. At this time, the anode electrode 31 and the cathode electrode 32 are conductively connected to a drive IC, not shown, for example. A signal voltage according to a display image is input from the driver IC to the plural anode electrodes 31 in synchronization with a clockpulse, and a scanning voltage is applied sequentially to the plural cathode electrodes 32.

In the case where the organic EL display 10 is constituted for color display, red light, blue light and yellow light may be emitted in the three adjacent display devices 20 sequentially, for example. At this time, light emitting substances may be mixed to the organic light-emitting layer 38 in order to emit color light, or the display devices 20 may be covered with color filters corresponding to the respective colors.

The electrodes and the grooves 43 can be formed in the following manner, for example. After photolithography, the anode electrodes 31 are deposited by vacuum evaporation or sputtering. Thereafter, the anode electrodes 31 are formed into a band shape by etching or sandblast. The grooves 43 are formed into a band shape by etching or sandblast. Thereafter, the cathode electrodes 32 are formed via the insulating layers 33 by vacuum evaporation or sputtering.

### SECOND EMBODIMENT

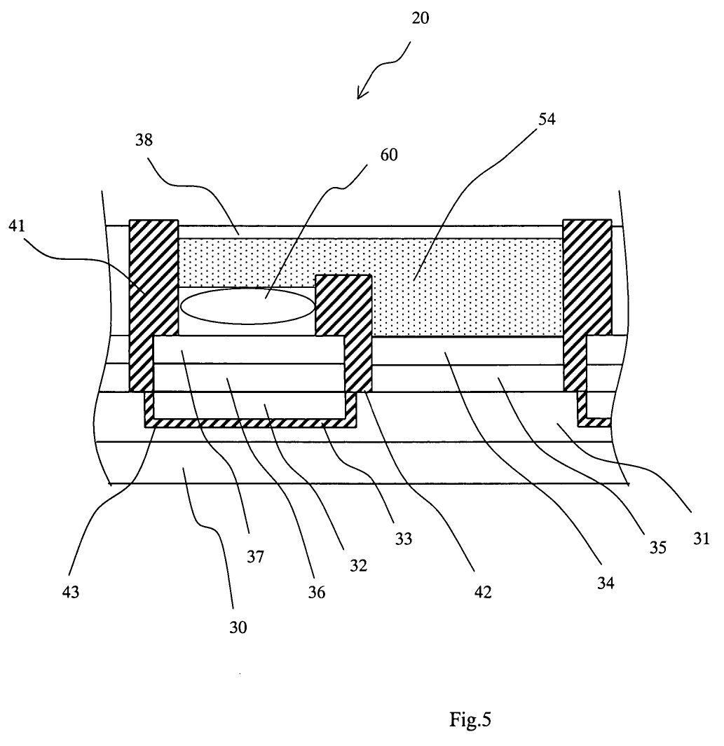

FIG. 5 illustrates a schematic constitutional diagram of the display device 20 according to the embodiment. The display device 20 according to this embodiment is a display device where the position where the carbon nanotube is mixed in the organic light-emitting layer 38 is different from the mixing position explained in the first embodiment. Since all the components such as the first electrode element other than the mixing position of the carbon nanotube in the display device 20 in this embodiment are similar to those explained in the first embodiment, the explanation thereof is not described. Further, in the organic EL display 10 shown in FIG. 4 using the display device 20 according to this embodiment, since all the components such as the first electrode element other than the organic light-emitting layer 38 of the display device 20 in this embodiment are similar to those explained in the first embodiment, the explanation thereof is not described.

In the display device 20 shown in FIG. 5, the carbon nanotube is mixed between the surface crossing the organic light-emitting layer 38 in the organic light-emitting layer 38 on the side closer to the cathode electrode 32 than the separator 42 and the hole transport layer 34, so that the organic light-emitting layer 54 including the carbon nanotube is formed. At this time, for example, the carbon nanotube covers the hole transport layer 34 and the cross surface and is mixed so that the organic light-emitting layer 54 including the carbon nanotube continues from the hole transport layer 34 to the cross surface.

When the carbon nanotube is mixed so as to cover the hole transport layer 34, the joint property can be satisfactorily in entire area of the joint portion between the organic light-emitting layer 54 including the carbon nanotube and the hole transport layer 34. Further, when the carbon nanotube is mixed so as to cover the cross surface and so that the organic light-emitting layer 54 including the carbon nanotube continues from the hole transport layer 34 to the cross surface, the electrons or the holes are allowed to securely pass through the organic light-emitting layer 54 including the carbon nanotube from the cross surface to the hole transport layer 34, so that the mixing of the carbon nanotube into the organic light-emitting layer 38 can be made to be effective. Since the work function of the carbon nanotube is small, the mixing of the carbon nanotube into the above position improves the joint property with respect to the hole transport layer 34. Further, the mixing of the carbon nanotube into the organic light-emitting layer 38 can improve the mobility of the holes in the organic light-emitting layer 38. For this reason, the electric resistance of the organic light-emitting layer 38 between the anode electrode 31 and the cathode electrode 32 can be small, so that the driving voltage can be reduced more than that of the display device having the organic light-emitting layer without the carbon nanotube.

Since the mobility of the holes in the organic light-emitting layer 38 is improved, it can be assumed that the holes are easily retained in the vicinity of the boundary surface of the organic light-emitting layer 54 including the carbon nanotube on the side of the cathode electrode 32, and the position where the holes and the electrons are recoupled can be moved to the vicinity of the boundary surface of the organic light-emitting layer 54 including the carbon nanotube on the side of the cathode electrode 32. For this reason, when the position of the boundary surface of the organic light-emitting layer 54 including the carbon nanotube on the side of the cathode electrode 32 is adjusted, the position of the light-emitting unit 60 can be finely adjusted. When the light emitted in the light-emitting layer 38 is emitted to the first direction, the transmitting distance of the light in the organic light-emitting layer 38 can be shortened, and the light emitting efficiency can be improved.

### EMBODIMENT 3

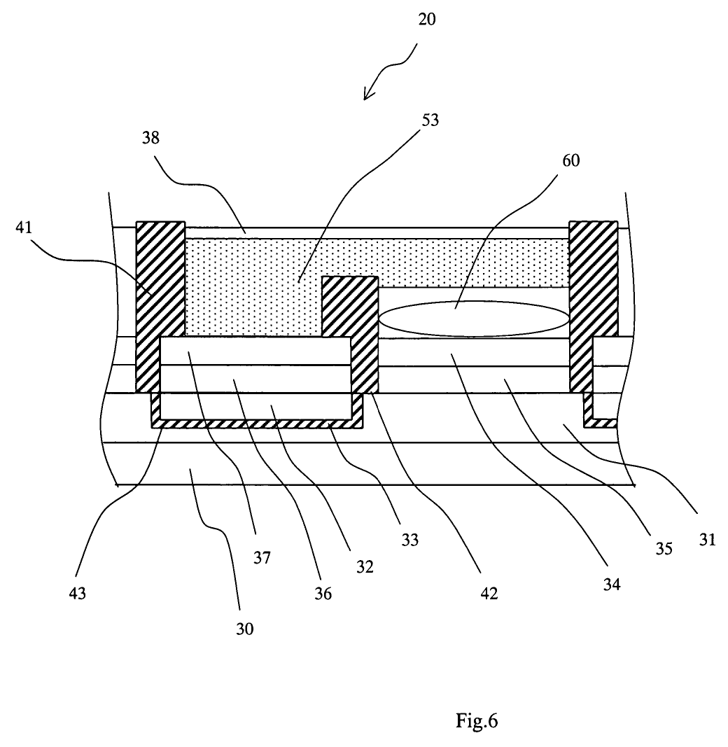

FIG. 6 illustrates a schematic constitutional diagram of the display device 20 according to this embodiment. The display device 20 according to this embodiment is a display device where the position where the carbon nanotube is mixed in the organic light-emitting layer 38 is different from the mixing position explained in the first embodiment. Since all the components such as the first electrode element other than the mixing position of the carbon nanotube in the display device 20 in this embodiment are similar to those explained in the first embodiment, the explanation thereof is not described. Further, in the organic EL display 10 using the display device 20 according to this embodiment, all the components such as the first electrode element other than the organic light-emitting layer 38 of the display device 20 in this embodiment are similar to those explained in the first embodiment, the explanation thereof is not described.

In the display device 20 shown in FIG. 6, the carbon nanotube is mixed between the surface crossing the organic light-emitting layer 38 in the organic light-emitting layer 38 on the side closer to the anode electrode 31 than the separator 42 and the electron transport layer 37, so that the organic light-emitting layer 53 including the carbon nanotube is formed. At this time, for example, the carbon nanotube covers the electron transport layer 37 and the cross surface and is mixed so that the organic light-emitting layer 53 including the carbon nanotube continues from the electron transport layer 37 to the cross surface.

When the carbon nanotube is mixed so as to cover the electron transport layer 37, the electrons easily move from the electron transport layer 37 to the organic light-emitting layer 53 including the carbon nanotube. Further, when the carbon nanotube is mixed so as to cover the cross surface and so that the organic light-emitting layer 53 including the carbon nanotube continues from the electron transport layer 37 to the cross surface, the electrons or the holes are allowed to securely pass through the organic light-emitting layer 53 including the carbon nanotube from the cross surface to the hole transport layer 34, thereby making the mixing of the carbon nanotube in the organic light-emitting layer 38 effective. When the carbon nanotube is mixed in the above position, the mobility of the electrons can be improved, and the organic light-emitting layer 53 including the carbon nanotube can serve as an electron discharge source. At this time, an applied voltage can be concentrated onto the light-emitting unit 60 in the organic light-emitting layer38. For this reason, the electric resistance of the organic light-emitting layer 38 between the anode electrode 31 and the cathode electrode 32 can be small, so that the driving voltage can be lower than that of the display device having the organic light-emitting layer 38 without the carbon nanotube.

When the mobility of the holes and the electrons in the organic light-emitting layer 38 is considered, it is assumed that the position where the electrons and the holes are recoupled is the vicinity of the boundary surface of the organic light-emitting layer 53 including the carbon nanotube on the side of the anode electrode 31. For this reason, when the position of the surface of the anode electrode 31 side among the boundary surfaces of the organic light-emitting layer 53 including the carbon nanotube is adjusted, the position of the light-emitting unit 60 can be finely adjusted. When the light emitted in the organic light-emitting layer 38 is emitted to the first direction, the transmission distance in the organic light-emitting layer 38 is shortened, so that the light emitting efficiency can be improved.

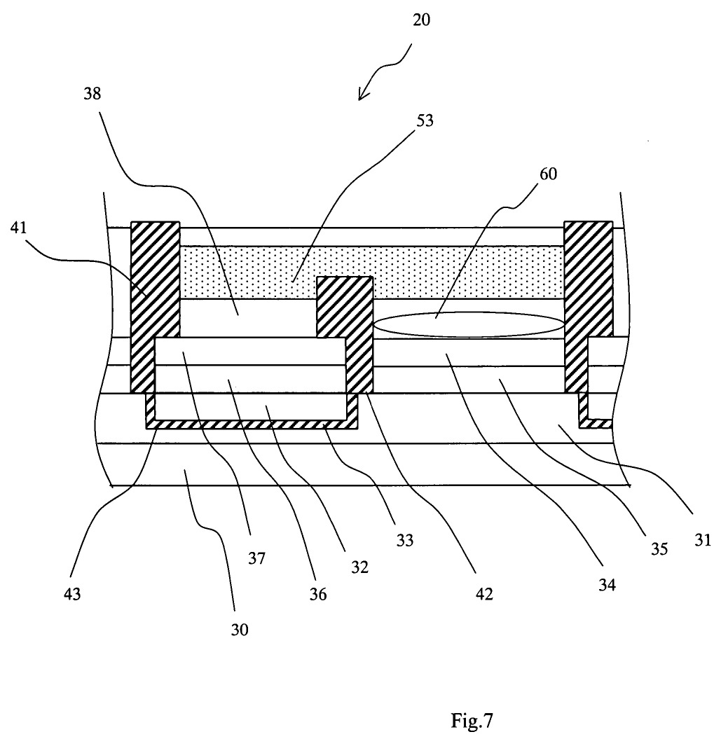

As shown in FIG. 7, the carbon nanotube may be mixed so as to cross the organic light-emitting layer 38 of the anode electrode 31 side from the position which does not contact with the electron transport layer 37. In the organic light-emitting layer 53 including the carbon nanotube shown in FIG. 7, since the electric resistance becomes lower than that of the organic light-emitting layer 38 without the carbon nanotube, the driving voltage can be lower than that of the display device having the organic light-emitting layer without carbon nanotube effectively.

### EMBODIMENT 4

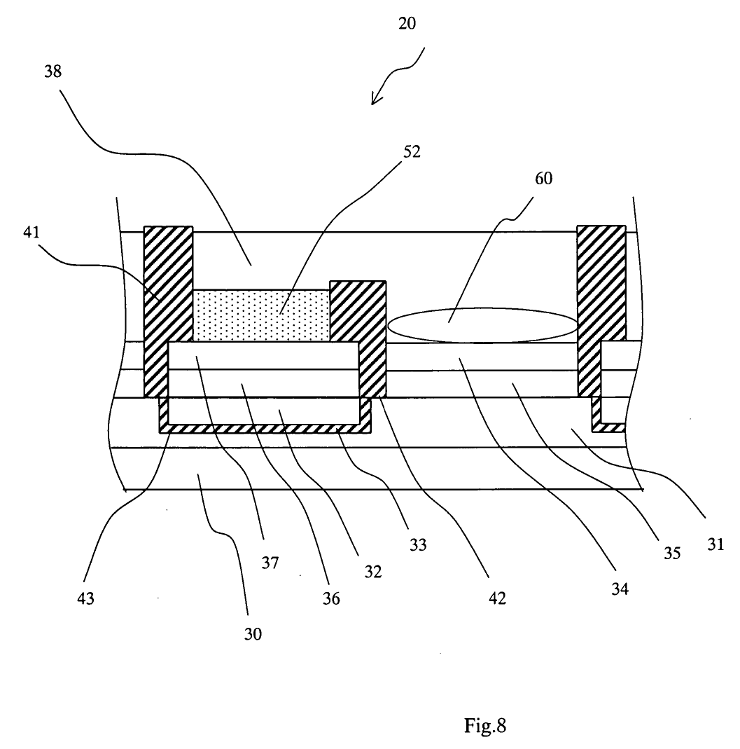

FIG. 8 illustrates a schematic constitutional diagram of the display device 20 according to this embodiment. The display device 20 in this embodiment is a display device where the mixing position of the carbon nanotube in the organic light-emitting layer 38 is different from the mixing position explained in the first embodiment. Since all the components such as the first electrode element other than the mixing position of the carbon nanotube in the display device 20 in this embodiment are similar to those explained in the first embodiment, the explanation thereof is not described. Further, in the organic EL display 10 using the display device 20 in this embodiment, since all the components such as the first electrode element other than the organic light-emitting layer 38 of the display device 20 in this embodiment are similar to those explained in the first embodiment, the explanation thereof is not described.

The carbon nanotube is mixed between the surface crossing the organic light-emitting layer 38 in the organic light-emitting layer 38 on the side closer to the cathode electrode 32 than the separator 42 and the electron transport layer 37, so that the organic light-emitting layer 52 including the carbon nanotube is formed in the display device 20 shown in FIG. 8. At this time, as shown in FIG. 8, for example, the carbon nanotube is mixed in the organic light-emitting layer 38 so as to cover the electron transport layer 37.

When the carbon nanotube is mixed so as to cover the electron transport layer 37, the electrons easily move from the electron transport layer 37 to the organic light-emitting layer 52 including the carbon nanotube. When the carbon nanotube is mixed in the above position, the mobility of the electrons can be improved, and the organic light-emitting layer 52 including the carbon nanotube can serve as an electron discharge source. At this time, an applied voltage can be concentrated on the light-emitting unit 60 in the organic light-emitting layer 38. For this reason, the electric resistance of the organic light-emitting layer 38 between the anode electrode 31 and the cathode electrode 32 can be small, so that the driving voltage can be lower than that of the display device having the organic light-emitting layer 38 without carbon nanotube.

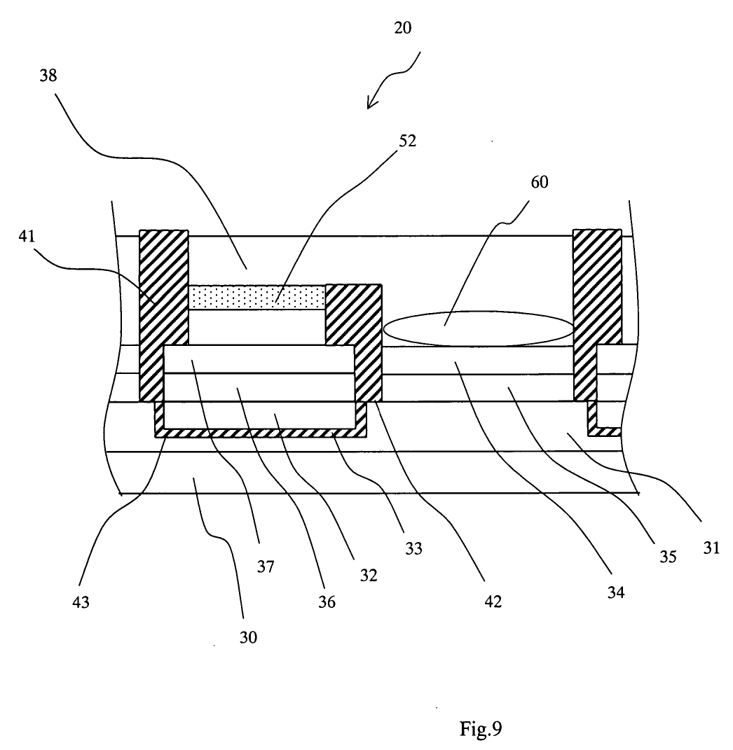

Further, as shown in FIG. 9, the carbon nanotube may be mixed in a position which does not contact with the electron transport layer 37. At this time, the carbon nanotube is mixed so as to cross the organic light-emitting layer 38 on the side closer to the cathode electrode 32 than the separator 42. In the organic light-emitting layer 52 including the carbon nanotube shown in FIG. 9, since the carbon nanotube has the function for improving the mobility of the electrons, its electric resistance becomes lower than that of the organic light-emitting layer 38 without carbon nanotube. For this reason, the driving voltage can be lower than that of the display device 20 having the organic light-emitting layer without carbon nanotube.

### EMBODIMENT 5

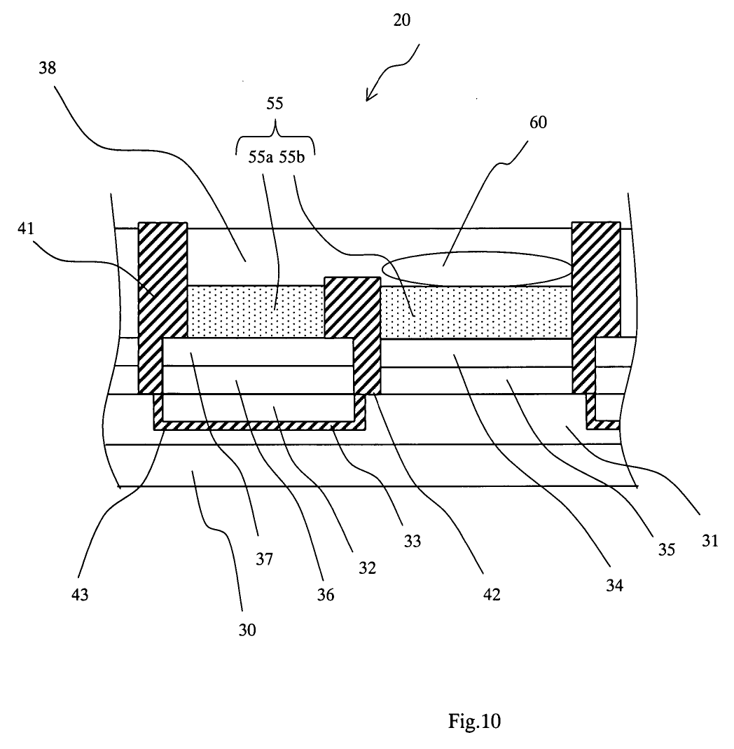

FIG. 10 illustrates a schematic constitutional diagram of the display device 20 in this embodiment. The display device 20 in this embodiment is a display device where the mixing position of the carbon nanotube in the organic light-emitting layer 38 is a combination of the mixing positions of the carbon nanotube explained in the first (FIG. 1) and fourth (FIG. 8) embodiments. Since all the components such as the first electrode element other than the mixing position of the carbon nanotube in the display device 20 in this embodiment are similar to those explained in the first embodiment, the explanation thereof is not described. In the organic EL display 10 using the display device 20 in this embodiment, since all the components such as the first electrode element other than the organic light-emitting layer 38 of the display device 20 in this embodiment are similar to those explained in the first embodiment, the explanation thereof is not described.

In the display device 20 shown in FIG. 10, the carbon nanotube is mixed between the surface crossing the organic light-emitting layer 38 in the organic light-emitting layer 38 on the side closer to the cathode electrode 32 than the separator 42 and the electron transport layer 37, so that the organic light-emitting layer 55a including the carbon nanotube is formed. The carbon nanotube is mixed between the surface crossing the organic light-emitting layer 38 in the organic light-emitting layer 38 on the side closer to the anode electrode 31 than the separator 42 and the hole transport layer 34, so that the organic light-emitting layer 55b including the carbon nanotube is formed. At this time, as shown in FIG. 10, for example, the carbon nanotube is mixed in the organic light-emitting layer 38 so as to cover the electron transport layer 37 on the side of the cathode electrode 32, and the carbon nanotube is mixed in the organic light-emitting layer 38 so as to cover the hole transport layer 34 on the side of the anode electrode 31.

When the carbon nanotube is mixed so as to cover the electron transport layer 37, as explained in the fourth embodiment, the electrons easily move from the electron transport layer 37 to the organic light-emitting layer 55a including the carbon nanotube, so that the mobility of the electrons is improved and the organic light-emitting layer 55a including the carbon nanotube can serve as the electron discharge source. As a result, the applied voltage can be concentrated on the light-emitting unit 60 in the organic light-emitting layer 38. As a result, the electric resistance of the organic light-emitting layer 38 between the anode electrode 31 and the cathode electrode 32 can be small, so that the driving voltage can be lower than that of the display device having the organic light-emitting layer 38 without the carbon nanotube.

When the carbon nanotube is mixed so as to cover the hole transport layer 34, as explained in the first embodiment, the joint property can be improved in the entire area of the joint portion between the organic light-emitting layer 55b including the carbon nanotube and the hole transport layer 34. Further, the holes can be easily retained in the vicinity of the boundary surface of the organic light-emitting layer 55b including the carbon nanotube on the side opposite to the hole transport layer 34. For this reason, when the light emitted in the light-emitting unit 60 is emitted to the first direction, the transmission distance of the light to be transmitted through the organic light-emitting layer 38 becomes short, so that the emitting efficiency can be improved.

1-19. (canceled)

20. An organic electroluminescent display comprising a plurality of display devices provided on a substrate, the display devices including:
a first electrode element arranged on the substrate;
a second electrode element arranged adjacently to the first electrode element;
an organic light-emitting element that emit light by means of an electric field supplied by the first electrode element and the second electrode element and is formed on the substrate so as to cover both the first electrode element and the second electrode element; and
a separator in a substrate laminating direction that is arranged between the first electrode element and the second electrode element and separates to insulate at least the first electrode element from the second electrode element;
wherein carbon nanotube is mixed into the organic light-emitting element.

21. The organic electroluminescent display according to claim 20, characterized in that the carbon nanotube is mixed between a surface crossing the organic light-emitting element in the organic light-emitting element on the side closer to the first electrode than the separator and the first electrode element.

22. The organic electroluminescent display according to claim 20, characterized in that the carbon nanotube is mixed between a surface crossing the organic light-emitting element in the organic light-emitting element on the side closer to the second electrode element than the separator and the second electrode element.

23. The organic electroluminescent display according to claim 20, characterized in that the carbon nanotube is mixed between a surface crossing the organic light-emitting element in the organic light-emitting element on the side closer to the first electrode than the separator and the first electrode element, and between a surface crossing the organic light-emitting element in the organic light-emitting element on the side closer to the second electrode element than the separator and the second electrode element.

24. The organic electroluminescent display according to claim 20, characterized in that the carbon nanotube is mixed between a surface crossing the organic light-emitting element in the organic light-emitting element on the side closer to the first electrode element than the separator and the second electrode element.

25. The organic electroluminescent display according to claim 20, characterized in that the carbon nanotube is mixed between a surface crossing the organic light-emitting element in the organic light-emitting element on the side closer to the second electrode element than the separator and the first electrode element.

26. The organic electroluminescent display according to claim 20, characterized in that at least one of the first electrode element and the second electrode element is formed transparently.

27. The organic electroluminescent display according to claim 20, characterized in that both the first electrode element and the second electrode element are made of a material having resistivity of smaller than 10⁻⁴ Ω·cm.

28. The organic electroluminescent display according to claim 20, characterized in that a plurality of the band-shaped first electrode elements are arranged in a line form, and a plurality of the band-shaped second electrode elements are arranged in a line form via an insulating layer so as to cross the first electrode elements.

29. The organic electroluminescent display according to any one of claims 20, characterized in that a plurality of band-shaped grooves are provided in a line form on the first electrode elements so as to cross the first electrode elements, the second electrode elements are arranged in the grooves, respectively, via the insulating layer, and a height of a boundary between the first electrode elements and the organic light-emitting element from the substrate is approximately equal to a height of a boundary between the second electrode elements and the organic light-emitting element from the substrate.

30. The organic electroluminescent display according to claim 20, characterized in that the first electrode element has an anode electrode side function element which is adjacent to the organic light-emitting element and has at least one of a hole transport function and a hole injecting function, or the second electrode element has a cathode electrode side function element which is adjacent to the organic light-emitting element and has at least one of an electron transport function and an electron injecting function, and the first electrode element serves as an anode and the second electrode element serves as a cathode.

31. The organic electroluminescent display according to claim 21, characterized in that the first electrode element has an anode side function element which is adjacent to the organic light-emitting element and has at least one of a hole transport function and a hole injecting function, or the second electrode element has a cathode side function element which is adjacent to the organic light-emitting element and has at least one of an electron transport function and an electron injecting function, and the first electrode element serves as an anode and the second electrode element serves as a cathode.

32. The organic electroluminescent display according to claim 22, characterized in that the first electrode element has an anode side function element which is adjacent to the organic light-emitting element and has at least one of a hole transport function and a hole injecting function, or the second electrode element has a cathode side function element which is adjacent to the organic light-emitting element and has at least one of an electron transport function and an electron injecting function, and the first electrode element serves as an anode and the second electrode element serves as a cathode.

33. The organic electroluminescent display according to claim 23, characterized in that the first electrode element has an anode side function element which is adjacent to the organic light-emitting element and has at least one of a hole transport function and a hole injecting function, or the second electrode element has a cathode side function element which is adjacent to the organic light-emitting element and has at least one of an electron transport function and an electron injecting function, and the first electrode element serves as an anode and the second electrode element serves as a cathode.

34. The organic electroluminescent display according to claim 24, characterized in that the first electrode element has an anode side function element which is adjacent to the organic light-emitting element and has at least one of a hole transport function and a hole injecting function, or the second electrode element has a cathode side function element which is adjacent to the organic light-emitting element and has at least one of an electron transport function and an electron injecting function, and the first electrode element serves as an anode and the second electrode element serves as a cathode.

35. The organic electroluminescent display according to claim 25, characterized in that the first electrode element has an anode side function element which is adjacent to the organic light-emitting element and has at least one of a hole transport function and a hole injecting function, or the second electrode element has a cathode side function element which is adjacent to the organic light-emitting element and has at least one of an electron transport function and an electron injecting function, and the first electrode element serves as an anode and the second electrode element serves as a cathode.
